(19) United States
(12) Patent Application Publication
(10) Pub. No.: US 2023/0291235 A1
(43) Pub. Date: Sep. 14, 2023

(54) CHARGING DEVICE

(71) Applicant: GUANGDONG OPPO MOBILE TELECOMMUNICATIONS CORP., LTD., Dongguan (CN)

(72) Inventor: Zhongyu AN, Dongguan (CN)

(21) Appl. No.: 18/317,487

(22) Filed: May 15, 2023

Related U.S. Application Data
(63) Continuation of application No. PCT/CN2021/115712, filed on Aug. 31, 2021.

(30) Foreign Application Priority Data
Nov. 16, 2020 (CN) 202011283404.8

(51) Int. Cl. H02J 50/00; H02J 50/10; H02J 7/00

(52) U.S. Cl. CPC H02J 50/005; H02J 50/10; H02J 7/0044

(57) ABSTRACT

A charging device is provided in the disclosure. The charging device can include a first housing, a second housing, a charging assembly, and a holder. The second housing is rotatably connected to the first housing and configured to hold an electronic device. The charging assembly is received in the second housing and configured to charge the electronic device. The holder is rotatable relative to the first housing and rotatable along with rotation of the second housing, and the holder is configured to switch between an extending-out state where a portion of the holder extends out of the first housing and a receiving state where the portion of the holder is received in the first housing.

### CROSS-REFERENCE TO RELATED APPLICATION(S)

This application is a continuation of International Application No. PCT/CN2021/115712, filed Aug. 31, 2021, which claims priority to Chinese Patent Application No. 202011283404.8, filed Nov. 16, 2020, the entire disclosures of which are incorporated herein by reference.

### TECHNICAL FIELD

This disclosure relates to the field of electronic product technology, and in particular, to a charging device.

### BACKGROUND

With the continuous development and popularization of electronic devices, the number of electronic devices is constantly increasing, and therefore, charging devices, as one of peripheral products of the electronic devices, also attract more and more attention.

### SUMMARY

In view of above, a charging device is provided in a first aspect of the disclosure. The charging device includes a first housing, a second housing, a charging assembly, and a holder. The second housing is rotatably connected to the first housing and configured to hold an electronic device. The charging assembly is received in the second housing and configured to charge the electronic device. The holder is rotatable relative to the first housing and rotatable along with rotation of the second housing, and the holder is configured to switch between an extending-out state where a portion of the holder extends out of the first housing and a receiving state where the portion of the holder is received in the first housing.

### BRIEF DESCRIPTION OF THE DRAWINGS

To describe technical solutions in implementations of the disclosure more clearly, the following will give an illustration to accompanying drawings required for describing implementations of the disclosure.

FIG. 1 is a schematic perspective structural view of a charging device in a horizontal state in an implementation of the disclosure.

FIG. 2 is a schematic cross-sectional view of the charging device in FIG. 1, taken along line A-A.

FIG. 3 is a schematic perspective structural view of a charging device in a vertical state in an implementation of the disclosure.

FIG. 4 is a schematic cross-sectional view of the charging device in FIG. 3, taken along line B-B.

FIG. 5 is an exploded view of a charging device in an implementation of the disclosure.

FIG. 6 is a schematic perspective structural view of a first housing in an implementation of the disclosure.

FIG. 7 is an exploded structural view of a portion of a charging device in an implementation of the disclosure.

FIG. 8 is a schematic cross-sectional view of the charging device in FIG. 1, taken along line C-C.

FIG. 9 is an exploded structural view of a portion of a charging device in another implementation of the disclosure.

FIG. 10 is a schematic cross-sectional view of the charging device in FIG. 1, taken along line D-D.

FIG. 11 is an exploded structural view of a portion of a charging device in yet another implementation of the disclosure.

FIG. 12 is a schematic cross-sectional view of the charging device in FIG. 1 in another implementation of the disclosure, taken along line D-D.

FIG. 13 is a schematic cross-sectional view of the charging device in FIG. 1 in another implementation of the disclosure, taken along line A-A.

FIG. 14 is an exploded view of a third sub-housing, a transmission member, and a holder in an implementation of the disclosure.

FIG. 15 is a schematic partial view of the charging device in FIG. 2.

FIG. 16 is a schematic perspective structural view of a transmission member in an implementation of the disclosure.

FIG. 17 is a schematic perspective structural view of a transmission member and a holder in an implementation of the disclosure.

FIG. 18 is a schematic structural view of an electronic structure of a charging device in an implementation of the disclosure.

FIG. 19 is a schematic structural view of an electronic structure of a charging device in another implementation of the disclosure.

FIG. 20 is a schematic structural view of an electronic structure of a charging device in yet another implementation of the disclosure.

FIG. 21 is a schematic structural view of an electronic structure of a charging device in yet another implementation of the disclosure.

FIG. 22 is an exploded view of a charging assembly in an implementation of the disclosure.

FIG. 23 is a schematic structural view of an electronic device assembly in an implementation of the disclosure.

FIG. 24 is a schematic cross-sectional view of the electronic device assembly in FIG. 23, taken along line E-E.

### REFERENCE SIGNS

charging device—1, electronic device—2, electronic device assembly—3, induction coil—4, battery —5, first housing—10, first receiving space—100, first surface—101, second surface—102, third surface—103, first sub-housing—11, second sub-housing—12, protruding portion—13, second receiving space—130, first side wall—14, second side wall—15, first rotation recess—16, first rotation shaft—160, first bearing—161, second rotation recess—17, second rotation shaft—170, slot—171, top wall—18, second through hole—180, third rotation recess—190, third rotation shaft—191, rotation frame—192, installation groove—193, second housing—20, third receiving space—200, third sub-housing—21, bottom wall—211, sidewall—212, first through hole—213, fourth sub-housing—22, charging assembly—30, charging coil—31, heat dissipation support—32, holder—40, positioning recess—41, anti-slip member—42, fixing hole—43, connecting rod shaft —44, motor assembly—50, processor—60, communication component—61, distance sensor—62, speaker—63, first switch—64, second switch—65, transmission member—70.

### DETAILED DESCRIPTION

The following are exemplary implementations of the disclosure, and it should be noted that for those of ordinary skill in the art, several modifications and embellishments made without departing from principles of the disclosure are also considered to fall within the protection scope of the disclosure.

A charging device is provided in implementations of the disclosure. The charging device can include a first housing, a second housing, a charging assembly, and a holder. The second housing is rotatably connected to the first housing and configured to hold an electronic device. The charging assembly is received in the second housing and configured to charge the electronic device. The holder is rotatable relative to the first housing and rotatable along with rotation of the second housing, and the holder is configured to switch between an extending-out state where a portion of the holder extends out of the first housing and a receiving state where the portion of the holder is received in the first housing.

The charging device can further include a transmission member connected to the holder and the second housing, where when the second housing rotates relative to the first housing, the second housing drives the holder to rotate through indirection cooperation between the transmission member and the holder.

The first housing can include a first sub-housing and a second sub-housing connected to the first sub-housing, where the first sub-housing and the second sub-housing cooperate to define a first receiving space. The first housing can further include a protruding portion provided at a side of the second sub-housing away from the first sub-housing, where the protruding portion has two opposite first side walls and a second side wall that is connected between the two first side walls. The first side walls and the second side wall cooperate to define a second receiving space connected to the first receiving space. The second housing is rotatably connected to the first side walls.

The first side wall defines a first rotation recess at a side close to the second receiving space, and the second housing can include a third sub-housing and a fourth sub-housing connected to the third sub-housing. The third sub-housing is closer to the first sub-housing than the fourth sub-housing, and the third sub-housing and the fourth sub-housing cooperate to define a third receiving space. The third sub-housing has a bottom wall and a sidewall that is connected to and bent relative to at least a portion of a periphery of the bottom wall, where the sidewall defines a first through hole. The charging device can further include a first rotation shaft, where the first rotation shaft has one end received in the third receiving space and connected to the third sub-housing, and the other end of the first rotation shaft penetrates the first through hole, and the other one end of the first rotation shaft is disposed at the outside of the third receiving space and received in the first rotation recess.

The first side wall defines a second rotation recess at a side close to the second receiving space. The charging device can further include a second rotation shaft, where the second rotation shaft has one end connected to the holder, and the other end of the second rotation shaft is received in the second rotation recess.

The holder defines a slot at a side close to the first sub-housing, and the end of the second rotation shaft is received in the slot.

The protruding portion further has a top wall connected to the two first side walls and the second side wall. The first side walls, the second side wall, and the top wall cooperate to define the second receiving space. The top wall defines a second through hole that is connected to the second receiving space, and the top wall defines a second rotation recess at a wall of the second through hole. The charging device can further include a second rotation shaft. The holder is partially received in the second through hole, and the second rotation shaft has an end connected to the holder, and the other end of the second rotation shaft is received in the second rotation recess.

When the holder is in the receiving state, a side surface of the holder away from the first sub-housing is flush with a side surface of the top wall away from the first sub-housing.

The first housing has a first surface, a second surface opposite the first surface, and a third surface connecting the first surface and the second surface, where the second surface is configured to partially abut against the second housing. When the holder is in the extending-out state, the holder extends out of the first housing from the second surface.

The charging device has a horizontal state and a vertical state. In the horizontal state, the second housing is parallel to the first housing, and in the vertical state, the second housing is angled relative to the first housing. When the charging device is in the vertical state, the holder is perpendicular to the second housing.

The charging device can further include an anti-slip member that is disposed at a side of the holder away from a first sub-housing.

The transmission member is partially received in the second receiving space, and the transmission member is connected to the holder and defines a third rotation recess. The charging device can further include a rotation frame and a third rotation shaft. The rotation frame is connected to the second housing at a side of the second housing close to the holder, and the third rotation shaft has an end connected to the rotation frame, and the other opposite end of the third rotation shaft is received in the third rotation recess.

The third rotation recess is in a shape of arc and extends towards the first sub-housing.

The third rotation recess extends in a direction parallel to a rotation direction of the third rotation shaft.

The transmission member defines an installation groove at a side close to the second housing, where the installation groove is connected to the third rotation recess.

The transmission member defines the third rotation recess at a side away from the first side wall, and the third rotation shaft has an end connected to the rotation frame at a side of the rotation frame close to the first side wall.

The holder defines a fixing hole at one end close to the first sub-housing, and the transmission member is provided with a connecting rod shaft received in the fixing hole.

The charging device can further include a motor assembly, where the motor assembly is received in the first receiving space, connected to the second housing, and configured to drive the second housing to rotate relative to the first housing.

The charging device can further include a processor received in the first receiving space. The processor is electrically connected to the motor assembly, configured to send a first control signal to the motor assembly to start the motor assembly, and further configured to send a second control signal to the motor assembly to stop the motor assembly.

The charging device can further include a distance sensor received in the first receiving space. The distance sensor is electrically connected to the processor and connected to the motor assembly. During operation of the motor assembly, the distance sensor is configured to send a distance signal to the processor, and the processor is further configured to obtain a rotation angle of the second housing according to the distance signal. The processor is further configured to determine whether the rotation angle of the second housing is greater than or equal to a preset angle, and further configured to send the second control signal to the motor assembly to stop the motor assembly in response to the rotation angle of the second housing being greater than or equal to the preset angle.

The charging device can further include a speaker received in the first receiving space and electrically connected to the processor. The processor is further configured to send an audio signal to the speaker to make the speaker sound when the processor sends the first control signal to the motor assembly. The processor is further configured to stop sending the audio signal to the speaker when the processor sends the second control signal to the motor assembly.

The charging device can further include a first switch and a second switch received in the first receiving space, where both the first switch and the second switch are electrically connected to the processor. The first switch is configured to send a vertical signal to the processor in response to pressing of the first switch, the processor is further configured to send the first control signal to the motor assembly according to the vertical signal, and the motor assembly is configured to drive the second housing to rotate in a first direction according to the first control signal. The second switch is configured to transmit a horizontal signal to the processor in response to pressing of the second switch, the processor is further configured to send a third control signal to the motor assembly according to the horizontal signal, and the motor assembly is configured to drive the second housing to rotate in a second direction according to the third control signal, where the first direction is opposite to the second direction.

The processor is further configured to obtain a pressing duration of the first switch according to the vertical signal and determine whether the pressing duration is less than a preset duration. The processor is configured to send the second control signal to the motor assembly in response to the pressing duration being less than the preset duration and the rotation angle of the second housing being equal to the preset angle. Alternatively, the processor is configured to send the second control signal to the motor assembly in response to the pressing duration being greater than or equal to the preset duration and removal of a touch force on the first switch.

The charging device can further include a communication component received in the first receiving space. The communication component is electrically connected to the processor and configured to receive a fourth control signal from a terminal device. The communication component is further configured to send the fourth control signal to the processor, and the processor is further configured to start or stop the motor assembly according to the fourth control signal.

The second housing can include a third sub-housing and a fourth sub-housing connected to the third sub-housing. The third sub-housing is closer to the first sub-housing than the fourth sub-housing, and the third sub-housing and the fourth sub-housing cooperate to define a third receiving space. The charging assembly is received in the third receiving space and can include a charging coil and a heat dissipation support. The charging coil is disposed on the heat dissipation support and electrically connected to the processor, the processor is further configured to send a charging signal to the charging coil, and the charging coil is configured to charge the electronic device according to the charging signal.

An electronic device assembly is provided in an implementation. The electronic device assembly can include an electronic device and the charging device as described in the above implementations of the disclosure. The electronic device can include an induction coil and a battery, and the charging coil and the induction coil cooperate to charge the battery.

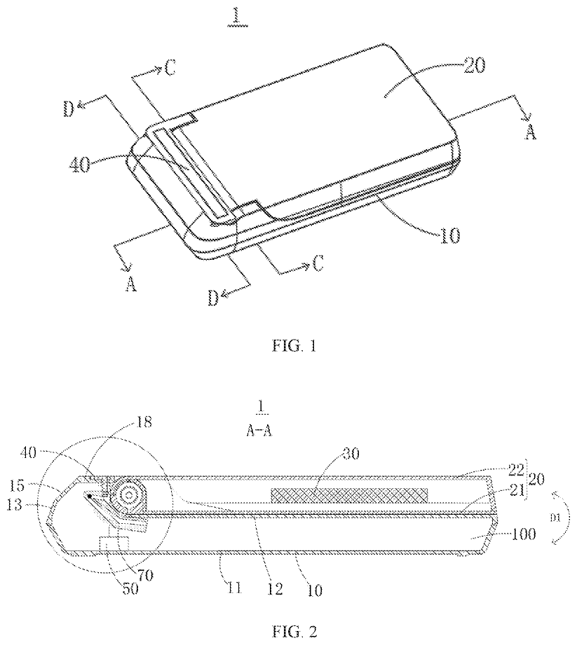

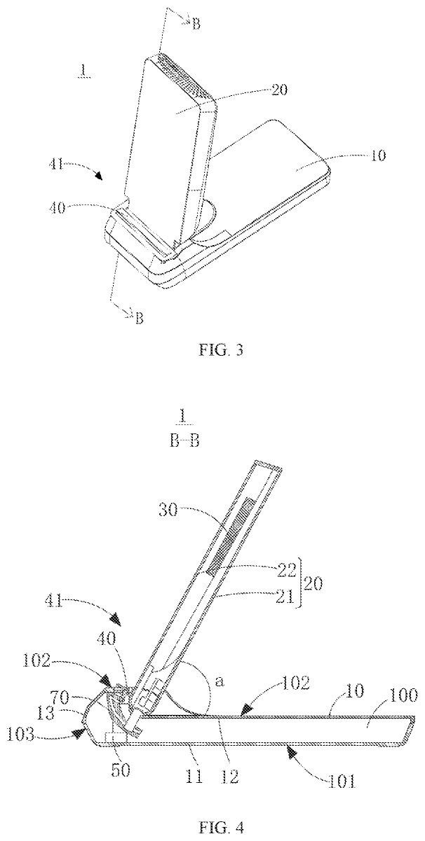

Referring to FIGS. 1-4 together, FIG. 1 is a schematic perspective structural view of a charging device in a horizontal state in an implementation of the disclosure, FIG. 2 is a schematic cross-sectional view of the charging device in FIG. 1, taken along line A-A, FIG. 3 is a schematic perspective structural view of the charging device in a vertical state in an implementation of the disclosure, and FIG. 4 is a schematic cross-sectional view of the charging device in FIG. 3, taken along line B-B. A charging device 1 is provided in an implementation. In particular, the charging device 1 can include a first housing 10, a second housing 20, a charging assembly 30, and a holder 40. The second housing 20 is rotatably connected to the first housing 10 and configured to hold an electronic device 2. The charging assembly 30 is received in the second housing 20 and configured to charge the electronic device 2. The holder 40 is rotatable relative to the first housing 10 and rotatable along with rotation of the second housing 20, and the holder 40 can switch between an extending-out state where a portion of the holder 40 extends out of the first housing 10 and a receiving state where the portion of the holder 40 is received in the first housing 10.

The charging device 1 provided in the implementation is mainly configured to charge the electronic device 2. The charging device 1 can be connected to an external power supply, and the charging device 1 regarded as an intermediate medium can use external electrical energy to charge the electronic device 2. Alternatively, the charging device 1 can include a battery 5 therein, and the charging device 1 can transfer electrical energy of the battery 5 to the electronic device 2 for charging. In addition, the electronic device 2 can include, but is not limited to, a mobile terminal device such as a mobile phone, a tablet computer, a notebook computer, a palmtop computer, a personal computer (PC), a personal digital assistant (PDA), a portable media player (PMP), a navigation apparatus, a wearable device, a smart bracelet, or a pedometer, or a fixed terminal device such as a digital television (TV), a desktop computer, etc. For example, the electronic device 2 is a mobile phone in the disclosure.

The charging device 1 provided in the implementation can include the first housing 10 and the second housing 20. The second housing 20 is configured to hold the electronic device 2. The first housing 10 can be understood as a lower housing, and the second housing 20 can be understood as an upper housing. The first housing 10 is rotatably connected to the second housing 20, and the second housing 20 is rotatable relative to the first housing 10, that is, the first housing 10 can always be in a stationary state, and the second housing 20 can rotate. A specific rotation direction of the second housing 20 is illustrated as direction D1 in FIG. 2. The electronic device 2 is placed on the second housing 20, and thus when the second housing 20 rotates relative to the first housing 10, the electronic device 2 also moves along with the second housing 20.

The vertical-horizontal conversion charging device 1 is provided in the implementation, that is, the charging device 1 may have two states including a horizontal state (as illustrated in FIG. 2) and a vertical state (as illustrated in FIG. 4). In the horizontal state, the second housing 20 is parallel to the first housing 10, which can also be understood as that the second housing 20 abuts against a surface of the first housing 10. In the vertical state, the second housing 20 is angled relative to the first housing 10, which can also be understood as that the second housing 20 has rotated relative to the first housing 10, and one end of the second housing 20 has rotated away from the first housing 10, and thus the second housing 20 and the first housing 10 are no longer parallel to each other, and define a certain included angle (illustrated as angle a in FIG. 4). Optionally, in the vertical state, the angle defined between the second housing 20 and the first housing 10 may be greater than 0° and less than 90°, i.e., 0°<a<90°. When the charging device 1 is in the vertical state, the electronic device 2 placed on the second housing 20 may also rotate along with the second housing 20, and the electronic device 2 can “stand up”, thereby meeting a requirement of a user that the user can view the electronic device 2 from different directions.

The charging device 1 provided in the implementation can further include the charging assembly 30 received in the second housing 20, and the charging assembly 30 is configured to charge the electronic device 2 in the implementation. Optionally, the charging device 1 may transmit electrical energy in a wired manner. Alternatively, the charging device 1 may transmit electrical energy in a wireless manner, e.g., the charging device 1 may be a wireless charging device 1. Therefore, the charging device 1 provided in the disclosure has two main functions, i.e., a vertical-horizontal conversion function and a charging function. Optionally, the charging assembly 30 can include a charging coil 31 (see FIG. 22), where the charging coil 31 is one of main components for charging the electronic device 2. The charging coil 31 may be a wired charging coil 31 or a wireless charging coil 31. For example, in the implementation, the charging coil 31 is the wireless charging coil 31, and in this case, the charging device 1 is the wireless charging device 1, thereby further improving convenience of usage of the charging device 1.

The charging device 1 provided in the implementation can further include the holder 40. The vertical-horizontal conversion charging device 1 is provided in the disclosure. When the charging device 1 is in the vertical state, the electronic device 2 may also stand up, however, in this case, the electronic device 2 may tend to slide off from the second housing 20 due to a gravity of the electronic device 2. Therefore, the holder 40 is provided in the implementation, and the holder 40 is used to abut against one end of the electronic device 2 to prevent the electronic device 2 from slipping off. Alternatively, it can also be understood as that when the charging device 1 is in the vertical state, the holder 40 and the second housing 20 can cooperate to define a positioning recess 41 to position the electronic device 2. Moreover, a position of the electronic device 2 relative to the second housing 20 is limited by the holder 40, and thus the position of the electronic device 2 relative to the charging assembly 30 can also be further limited, thereby improving charging efficiency and charging stability of the charging device 1.

However, in a charging device in the related art, a holder of the charging device always protrudes from a housing of the charging device, which can also be understood as that the holder is fixedly connected to the second housing. In this way, when the charging device is in the vertical state, the effect described above can be achieved. However, when the charging device is in the horizontal state, the holder still always protrudes from the housing, thus affecting surface flatness of the charging device. Moreover, due to the holder, an electronic device cannot be placed at will when the charging device is in the horizontal state, and thus the position of the electronic device is limited, significantly affecting an aesthetic feeling of the charging device, and reducing an appearance performance of the charging device.

To solve the above problems, the holder 40 is designed to be movable in the disclosure, i.e., the holder 40 can perform accompanying rotation along with rotation of the second housing 20, and the holder 40 can switch between an extending-out state where the holder 40 extends out of the first housing 10 and a receiving state where the holder 40 is received in the first housing 10. “Accompanying rotation” means that when the second housing 20 rotates relative to the first housing 10, the holder 40 can rotate along with rotation of the second housing 20, which can also be understood as that when the second housing 20 rotates, the second housing 20 can drive the holder 40 to rotate together with the second housing 20. Optionally, as long as the second housing 20 rotates, the holder 40 can perform accompanying rotation. Alternatively, when the second housing 20 rotates to a certain extent, the holder 40 starts accompanying rotation.

In addition, the holder 40 can rotate relative to the first housing 10 in the implementation. Optionally, the holder 40 is rotatably connected to the first housing 10. In the implementation, the holder 40 is rotatably connected to the first housing 10, such that the holder 40 and the second housing 20 can define a certain included angle. During rotation of the second housing 20 relative to the first housing 10, various included angles can be defined. Compared with the charging device in the related art in which an included angle defined between the holder and the housing is fixed, requirements for different angles can be met in the implementation. Secondly, since the holder 40 is rotatably connected to the first housing 10, a distance between an end of the holder 40 and an end of the second housing 20 increases compared with the related art, and thus in the case of limiting the electronic device 2 of the same size, the second housing 20 can be reduced in size, accordingly the whole charging device 1 is reduced in size.

In addition, accompanying rotation of the holder 40 makes that the holder 40 can switch between the extending-out state where the portion of the holder 40 extends out of the first housing 10 and the receiving state where the portion of the holder 40 is received in the first housing 10. The receiving state can be understood as a state where the holder 40 is received in the first housing 10 when the charging device 1 is in the horizontal state, that is, a state where the holder 40 does not extend out of the first housing 10. The extending-out state can be understood as a state where the holder 40 extends out of the first housing 10, which is caused by accompanying rotation of the holder 40 duration rotation of the second housing 20 relative to the first housing 10 to a certain position or to the vertical state. In this way, the holder 40 has two functions. For example, when the charging device 1 is in the vertical state, the holder 40 may extend out of the first housing 10 for abutting against the electronic device 2. When the charging device 1 is in the horizontal state, the holder 40 may be received in the first housing 10, and the holder 40 does not extend out of the surface of the charging device 1, thereby improving surface flatness of the charging device 1. Moreover, the electronic device 2 can be placed at will, which improves convenience of usage of the charging device 1. In addition, when the charging device 1 is in the horizontal state, the holder 40 is received in the first housing 10, which can also improve an appearance performance of the charging device 1.

Optionally, it can be considered that when a surface of the holder 40 away from the second housing 20 is flush with a surface of the first housing 10 away from the second housing 20, the holder 40 is in the receiving state or the extending-out state. For example, in the implementation, the holder 40 is in the receiving state when the holder 40 is flush with the surface of the first housing 10 away from the second housing 20.

Optionally, when the holder 40 is in the extending-out state, the holder 40 can partially extend out of the first housing 10, or the holder 40 can fully extend out of the first housing 10. For example, in the implementation, the holder 40 partially extends out of the first housing 10.

To sum up, in the implementation, the holder 40 is rotatable along with rotation of the second housing 20, and thus the holder 40 can switch between the extending-out state and the receiving state, and not only the holder 40 can limit the electronic device 2 in the vertical state, but also surface flatness of the charging device 1 in the horizontal state can be improved, thereby improving diversity, convenience, and an appearance performance of the charging device 1. As for a specific structure of the charging device 1 and how the holder 40 rotates along with the second housing 20, the following will explain in detail.

Referring to FIG. 2, FIG. 4, and FIG. 5 together, FIG. 5 is an exploded view of the charging device in an implementation of the disclosure. In the implementation, the charging device 1 can further include a transmission member 70 connected to the holder 40 and the second housing 20. When the second housing 20 rotates relative to the first housing 10, the second housing 20 drives the holder 40 to rotate through indirection cooperation between the transmission member 70 and the holder 40.

When the second housing 20 rotates, the second housing 20 can directly drive the holder 40 to rotate. For example, when the second housing 20 rotates, the second housing 20 can abut against the holder 40 to drive the holder 40 to rotate relative to the first housing 10. Alternatively, as illustrated in the implementation, the transmission member 70 is provided and connected to the holder 40 and the second housing 20. In this way, when the second housing 20 rotates relative to the first housing 10, the second housing 20 drives the holder 40 to rotate through indirection cooperation between the transmission member 70 and the holder 40. It can also be understood as that when the second housing 20 rotates, the second housing 20 can drive the transmission member 70 connected to the second housing 20 to rotate. When the transmission member 70 rotates, the holder 40 connected to the transmission member 70 can be driven to rotate, thereby finally realizing that the holder 40 switches between the extending-out state and the receiving state. As for a more specific movement process, the following will describe in detail in the disclosure.

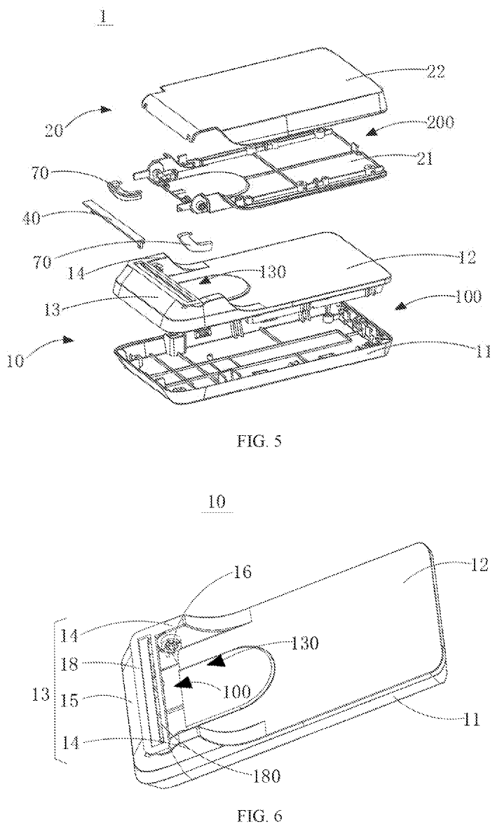

In the disclosure, a structure of each component and cooperation between multiple components will be described in detail. A structure of the first housing 10 is introduced first in the disclosure. Referring to FIG. 5 and FIG. 6 together, FIG. 6 is a schematic perspective structural view of the first housing in an implementation of the disclosure. In the implementation, the first housing 10 can include a first sub-housing 11 and a second sub-housing 12 connected to the first sub-housing 11. The first sub-housing 11 and the second sub-housing 12 cooperate to define a first receiving space 100. The first housing 10 can further include a protruding portion 13 provided at a side of the second sub-housing 12 away from the first sub-housing 11. The protruding portion 13 has two opposite first side walls 14 and a second side wall 15 that is connected between the two first side walls 14. The first side walls 14 and the second side wall 15 cooperate to define a second receiving space 130 connected to the first receiving space 100. The second housing 20 is rotatably connected to the first side walls 14.

In the implementation, the first housing 10 is not a conventional housing structure but consisted of the first sub-housing 11, the second sub-housing 12, and the protruding portion 13. The second sub-housing 12 and the protruding portion 13 may be of an integrated structure or a split-type structure. In the case where the second sub-housing 12 and the protruding portion 13 are of an integrated structure, it can be understood as that the first housing 10 is artificially split into the second sub-housing 12 and the protruding portion 13 for facilitating clear understanding of structural features of the second sub-housing 12 and the protruding portion 13.

In the implementation, the first housing 10 has a certain protruding structure due to the protruding portion 13, facilitating rotatable connection between the second housing 20 and the first housing 10. Moreover, the first side walls 14 and the second side wall 15 cooperate to define the second receiving space 130. The second receiving space 130 is configured to receive structural members such as the transmission member 70 and the holder 40, thereby providing an installation space for these members and improving an appearance performance of the charging device 1. Furthermore, the second housing 20 is rotatably connected to the first side walls 14. Optionally, the second housing 20 is rotatably connected to the two first side walls 14, thereby improving a rotational performance of the second housing 20.

In addition, the second receiving space 130 is connected to the first receiving space 100. The second housing 20 may drive rotation members to rotate together duration rotation of the second housing 20, and thus some rotation members originally received in the second receiving space 130 can also rotate into the first receiving space 100, thereby reserving a rotation space for the rotation members. Moreover, a motor assembly 50 may be further provided in the first receiving space 100. The motor assembly 50 is configured to drive the second housing 20 to rotate, and a connection space needs to be reserved for connection between the second housing 20 and the motor assembly 50.

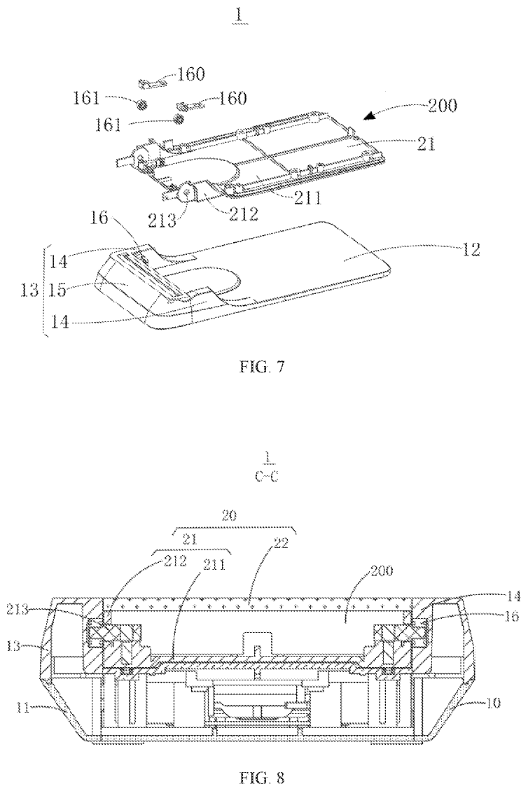

Referring to FIGS. 5-8 together, FIG. 7 is an exploded structural view of a portion of the charging device in an implementation of the disclosure, and FIG. 8 is a schematic cross-sectional view of the charging device in FIG. 1, taken along line C-C. In the implementation, the first side wall 14 defines a first rotation recess 16 at a side close to the second receiving space 130. The second housing 20 can include a third sub-housing 21 and a fourth sub-housing 22 connected to the third sub-housing 21. The third sub-housing 21 is closer to the first sub-housing 11 than the fourth sub-housing 22. The third sub-housing 21 and the fourth sub-housing 22 cooperate to define a third receiving space 200. The third sub-housing 21 has a bottom wall 211 and a sidewall 212 that is connected to and bent relative to at least a portion of a periphery of the bottom wall 211. The sidewall 212 defines a first through hole 213. The charging device 1 can further include a first rotation shaft 160. The first rotation shaft 160 has one end received in the third receiving space 200 and connected to the third sub-housing 21, and the other end of the first rotation shaft 160 penetrates the first through hole 213, and the other one end of the first rotation shaft 160 is disposed at the outside of the third receiving space 200 and received in the first rotation recess 16.

The following will introduce in detail how the second housing 20 is rotatably connected to the first side wall 14 in the implementation. The first side wall 14 defines the first rotation recess 16 at the side close to the second receiving space 130. The second housing 20 can include the third sub-housing 21 and the fourth sub-housing 22, and the third sub-housing 21 is closer to the first sub-housing 11 and the second sub-housing 12. Therefore, it can also be understood as that the fourth sub-housing 22 can be configured to hold and carry the electronic device 2. The third sub-housing 21 and the fourth sub-housing 22 cooperate to define the third receiving space 200 in which structural members such as the first rotation shaft 160 and the charging assembly 30 can be received. The third sub-housing 21 can include the bottom wall 211 and the sidewall 212, and the sidewall 212 defines the first through hole 213. Therefore, one end of the first rotation shaft 160 can be received in the third receiving space 200 and connected to the third sub-housing 21 by, for example, a screw, and the other end of the first rotation shaft 160 can penetrate the first through hole 213 of the sidewall 212 and be received in the first rotation recess 16. In this way, the second housing 20 can rotate relative to the first housing 10 through cooperation between the first rotation recess 16 and the first rotation shaft 160. Specifically, since an end of the first rotation shaft 160 is connected to the third sub-housing 21, when the first rotation shaft 160 rotates in the first rotation recess 16, the third sub-housing 21 can be driven by the first rotation shaft 160 to rotate. Similarly, the fourth sub-housing 22 can also be driven by the third sub-housing 21 to rotate.

Optionally, the first rotation shaft 160 is further sleeved with a first bearing 161 at the other end, and the first bearing 161 is received in the first rotation recess 16, and a rotation performance of the first rotation shaft 160 can further be improved through cooperation between the first bearing 161 and the first rotation shaft 160.

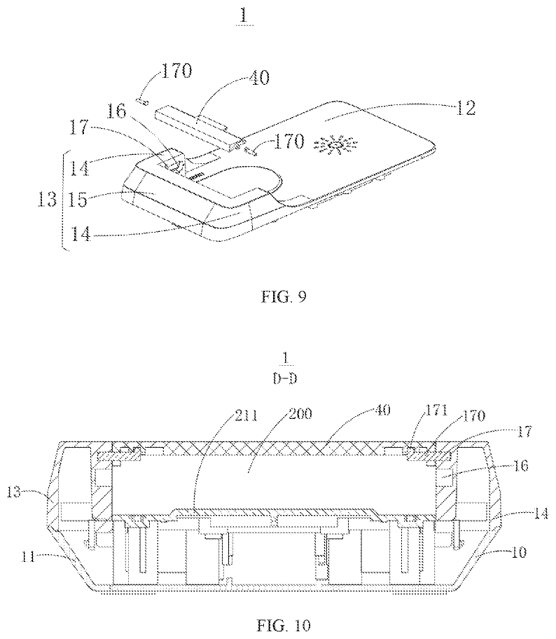

The following will introduce in detail cooperation between the holder 40 and the first housing 10. Referring to FIGS. 9-10 together, FIG. 9 is an exploded structural view of a portion of the charging device in another implementation of the disclosure, and FIG. 10 is a schematic cross-sectional view of the charging device in FIG. 1, taken along line D-D. In the implementation, the first side wall 14 defines a second rotation recess 17 at the side close to the second receiving space 130. The charging device 1 can further include a second rotation shaft 170, and the second rotation shaft 170 has one end connected to the holder 40, and the other end of the second rotation shaft 170 is received in the second rotation recess 17.

Two specific implementation manners in which the holder 40 is rotatably connected to the first side wall 14 are provided in the implementation. In the first implementation manner provided in the disclosure, the first side wall 14 defines the second rotation recess 17, an end of the second rotation shaft 170 is connected to the holder 40, and the other end of the second rotation shaft 170 is received in the second rotation recess 17. In this way, rotation of the second rotation shaft 170 in the second rotation recess 17 can drive the holder 40 to rotate together with the second rotation shaft 170. For a specific rotation process, reference can be made to the rotation process of the first rotation shaft 160.

Optionally, the holder 40 defines a slot 171 at a side close to the first sub-housing 11, and an end of the second rotation shaft 170 is received in the slot 171.

In the implementation, the holder 40 can define the slot 171 at the side (i.e., a lower side of the holder 40) close to the first sub-housing 11, and an end of the second rotation shaft 170 is received in the slot 171, and thus it can be realized that the second rotation shaft 170 is connected to the holder 40 at an end of the second rotation shaft 170. Moreover, an end of the second rotation shaft 170 is received in the slot 171, which can also facilitate installation of the holder 40 and the second rotation shaft 170. Specifically, the other end of the second rotation shaft 170 can be placed in the second rotation recess 17 first, then the holder 40 can be placed, and then an end of the second rotation shaft 170 can be automatically snapped into the slot 171 by rotation of the second rotation shaft 170, thus realizing installation.

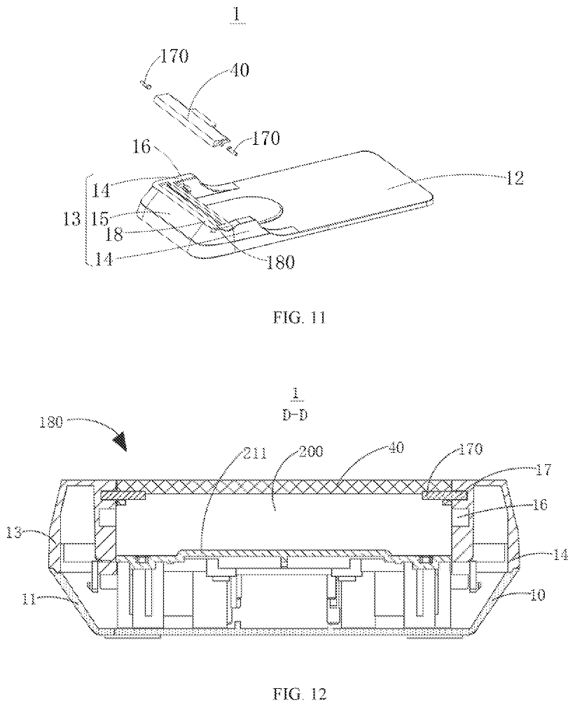

Referring to FIGS. 11-12 together, FIG. 11 is an exploded structural view of a portion of the charging device in yet another implementation of the disclosure, and FIG. 12 is a schematic cross-sectional view of the charging device in FIG. 1 in another implementation of the disclosure, taken along line D-D. In the implementation, the protruding portion 13 further has a top wall 18 connected to the two first side walls 14 and the second side wall 15. The first side walls 14, the second side wall 15, and the top wall 18 cooperate to define the second receiving space 130. The top wall 18 defines a second through hole 180 that is connected to the second receiving space 130. The second rotation recess 17 is defined at a wall of the second through hole 180 of the top wall 18. The charging device 1 can further include the second rotation shaft 170. The holder 40 is partially received in the second through hole 180. The second rotation shaft 170 has an end connected to the holder 40, and the other end of the second rotation shaft 170 is received in the second rotation recess 17.

In the second implementation manner provided in the disclosure, the protruding portion 13 further has the top wall 18. The first side walls 14, the second side wall 15, and the top wall 18 cooperate to define the second receiving space 130. The top wall 18 defines the second through hole 180 that is connected to the second receiving space 130. In the implementation, the holder 40 may be partially received in the second through hole 180, and the second rotation recess 17 is defined at the wall of the second through hole 180. In addition, the second rotation shaft 170 has one end connected to the holder 40, and the other end of the second rotation shaft 170 is received in the second rotation recess 17, and the holder 40 is rotatable in the second through hole 180 through cooperation between the second rotation shaft 170 and the second rotation recess 17. In the implementation, the second rotation shaft 170 is received in the second through hole 180, that is, a portion of the top wall 18 is arranged between the second housing 20 and the holder 40, and the holder 40 can be effectively protected by the portion of the top wall 18, thereby avoiding collision between the second housing 20 and the holder 40 during rotation of the second housing 20.

Referring to FIG. 2 again, in the implementation, when the holder 40 is in the receiving state, a side surface of the holder 40 away from the first sub-housing 11 is flush with a side surface of the top wall 18 away from the first sub-housing 11.

When the holder 40 is in the receiving state, i.e., the holder 40 is not rotated, the side surface of the holder 40 away from the first sub-housing 11 is flush with the side surface of the top wall 18 away from the first sub-housing 11. The side surface of the holder 40 away from the first sub-housing 11 and the side surface of the top wall 18 away from the first sub-housing 11 can constitute an abutting surface of the charging device 1 for abutting against the electronic device 2. Therefore, the side surface of the holder 40 away from the first sub-housing 11 is flush with the side surface of the top wall 18 away from the first sub-housing 11, and surface flatness of the charging device 1 can be improved.

Optionally, the side surface of the holder 40 away from the first sub-housing 11, the side surface of the top wall 18 away from the first sub-housing 11, and a side surface of the fourth sub-housing 22 away from the first sub-housing 11 are flush with one another, thereby further improving surface flatness of the charging device 1, and the electronic device 2 can be placed arbitrarily on the charging device 1 by the user when the charging device 1 is in the horizontal state.

Referring to FIG. 4 again, in the implementation, the first housing 10 has a first surface 101, a second surface 102 opposite the first surface 101, and a third surface 103 connecting the first surface 101 and the second surface 102. The second surface 102 is configured to partially abut against the second housing 20. When the holder 40 is in the extending-out state, the holder 40 extends out of the first housing 10 from the second surface 102.

The first housing 10 has the first surface 101, the second surface 102, and the third surface 103. As illustrated in FIG. 4, the first surface 101 can be understood as a lower surface of the first housing 10, and the second surface 102 can be understood as an upper surface of the first housing 10. The second surface 102 is not consisted of a single component but consisted of both the second sub-housing 12 and the protruding portion 13. The third surface 103 can be understood as a side surface of the first housing 10. Similarly, the third surface 103 is not consisted of a single component but consisted of both the first sub-housing 11 and the protruding portion 13. In the implementation, when the holder 40 is in the extending-out state, the holder 40 extends out of the first housing 10 from the second surface 102, instead of extending out of the first housing 10 from the first surface 101 or the third surface 103. The electronic device 2 is placed on the fourth sub-housing 22 when the charging device 1 is in the horizontal state, and thus in the case where the holder 40 extends from the second surface 102 of the first housing 10 (i.e. extends from the top wall 18), it is conducive for the electronic device 2 to abutting against the holder 40, thereby simplifying the structure of the charging device 1 and reducing the size of the charging device 1.

Referring to FIG. 4 again, in the implementation, the charging device 1 has a horizontal state and a vertical state. In the horizontal state, the second housing 20 is parallel to the first housing 10, and in the vertical state, the second housing 20 is angled relative to the first housing 10. When the charging device 1 is in the vertical state, the holder 40 is perpendicular to the second housing 20.

The above already explain in detail what the horizontal state and the vertical state are, which will not be repeated in the implementation. When the charging device 1 is in the vertical state, the holder 40 is perpendicular to the second housing 20, thereby further improving limiting of the electronic device 2.

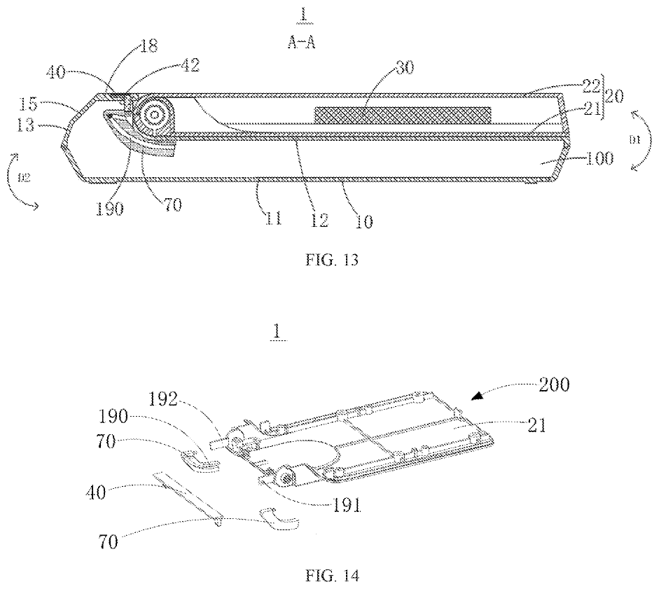

Referring to FIG. 13 together, FIG. 13 is a schematic cross-sectional view of the charging device in FIG. 1 in another implementation of the disclosure, taken along line A-A. In the implementation, the charging device 1 can further include an anti-slip member 42, and the anti-slip member 42 is disposed at a side of the holder 40 away from the first sub-housing 11.

In the implementation, the anti-slip member 42 is provided and disposed at the side of the holder 40 away from the first sub-housing 11, which can also be understood as that the anti-slip member 42 is disposed at an upper side of the first sub-housing 11. Limiting of the electronic device 2 by the holder 40 can be further improved through a high friction coefficient and an anti-slip performance of the anti-slip member 42.

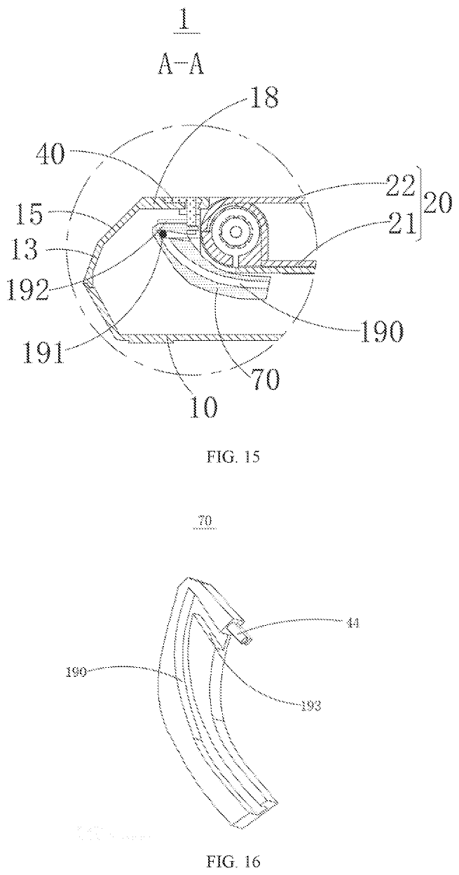

The following will introduce in detail cooperation between the transmission member 70 and the holder 40 and cooperation between the transmission member 70 and the second housing 20. Referring to FIGS. 14-16 together, FIG. 14 is an exploded view of the third sub-housing, the transmission member, and the holder in an implementation of the disclosure, FIG. 15 is a schematic partial view of the charging device in FIG. 2, and FIG. 16 is a schematic perspective structural view of the transmission member in an implementation of the disclosure. In the implementation, the transmission member 70 is partially received in the second receiving space 130, and the transmission member 70 is connected to the holder 40 and defines a third rotation recess 190. The charging device 1 can further include a rotation frame 192 and a third rotation shaft 191. The rotation frame 192 is connected to the second housing 20 at a side of the second housing 20 close to the holder 40. The third rotation shaft 191 has an end connected to the rotation frame 192, and another opposite end of the third rotation shaft 191 is received in the third rotation recess 190.

In the implementation, the transmission member 70 is partially received in the second receiving space 130 and partially received in the first receiving space 100, and the transmission member 70 is connected to the holder 40 and further defines the third rotation recess 190.

In addition, the rotation frame 192 is connected to the second housing 20 at the side of the second housing 20 close to the holder 40, and the rotation frame 192 and the second housing 20 may be of an integrated structure or a split-type structure. For example, in the implementation, the rotation frame 192 and the second housing 20 are of an integrated structure, which can also be understood as that the rotation frame 192 protrudes from the side surface of the second housing 20 close to the holder 40. Optionally, the rotation frame 192 can be connected to the third sub-housing 21.

In the implementation, the third rotation shaft 191 can also be provided, where the third rotation shaft 191 has one end connected to the rotation frame 192, and the other end of the third rotation shaft 191 is received in the third rotation recess 190. In this way, when the second housing 20 rotates, the second housing 20 can drive the rotation frame 192 to rotate, and then the third rotation shaft 191 can be driven to rotate in the third rotation recess 190. When the third rotation shaft 191 rotates in the third rotation recess 190, the transmission member 70 is subject to a force of the third rotation shaft 191, the transmission member 70 rotates in a direction opposite a rotation direction of the third rotation shaft 191, then the holder 40 also is driven to rotate in the direction opposite the rotation direction of the third rotation shaft 191, and the holder 40 can switch between the extending-out state and the receiving state.

Optionally, there are two rotation frames 192, two transmission members 70, and two third rotation shafts 191, which are symmetrically arranged along the second housing 20, thereby improving uniformity and stability of rotation of the second housing 20.

Referring to FIG. 17 together, FIG. 17 is a schematic perspective structural view of the transmission member and the holder in an implementation of the disclosure. In the implementation, the holder 40 defines a fixing hole 43 at one end close to the first sub-housing 11, and the transmission member 70 is provided with a connecting rod shaft 44 received in the fixing hole 43.

As mentioned above, the transmission member 70 is connected to the holder 40. In the implementation, the holder 40 defines the fixing hole 43 at the end close to the first sub-housing 11, and the transmission member 70 is provided with the connecting rod shaft 44 received in the fixing hole 43, thereby realizing plugging of the transmission member 70 into the holder 40 and facilitating installation and disassembly of the holder 40 and the transmission member 70.

Referring to FIG. 16 again, in the implementation, the third rotation recess 190 is in a shape of arc and extends towards the first sub-housing 11.

In the implementation, movement of the transmission member 70 depends on rotation of the third rotation shaft 191. The third rotation shaft 191 moves in an arc-shaped track, and thus the third rotation recess 190 is also designed in the shape of arc in the implementation, and it is easy for the third rotation shaft 191 to rotate in the third rotation recess 190. In addition, in the implementation, the third rotation recess 190 extends towards the first sub-housing 11, and it is easy for the third rotation shaft 191 to drive the transmission member 70 to rotate. Optionally, in the disclosure, a rotation speed of the transmission member 70 may be changed by design of the shape of the third rotation recess 190.

Referring to FIGS. 13 and 16 again, in the implementation, the third rotation recess 190 extends in a direction parallel to a rotation direction of the third rotation shaft 191.

In the implementation, the third rotation recess 190 extends in the direction parallel to the rotation direction of the third rotation shaft 191, and a force of the third rotation shaft 191 can be uniformly exerted on the transmission member 70 when the third rotation shaft 191 rotates, thereby further improving uniformity of rotation of the transmission member 70.

Referring to FIG. 16 again, in the implementation, the transmission member 70 defines an installation groove 193 at a side close to the second housing 20, where the installation groove 193 is connected to the third rotation recess 190.

In the implementation, the installation groove 193 connected to the third rotation recess 190 is also be provided and is defined on a side surface of the transmission member 70 close to the second housing 20, thereby facilitating installation of the third rotation shaft 191. For example, the third rotation shaft 191 can enter the installation groove 193 from the side surface of the transmission member 70 close to the second housing 20, and then enter the third rotation recess 190 from the installation groove 193 to wait for rotation of the second housing 20.

Referring to FIG. 5 again, in the implementation, the transmission member 70 defines the third rotation recess 190 at a side away from the first side wall 14, and the third rotation shaft 191 has an end connected to the rotation frame 192 at a side of the rotation frame 192 close to the first side wall 14.

In the implementation, the third rotation recess 190 is defined at the side of the transmission member 70 away from the first side wall 14, and the third rotation shaft 191 is connected to the rotation frame 192 at the side of the rotation frame 192 close to the first side wall 14, thereby reducing a difficulty of cooperation between the transmission member 70 and the third rotation shaft 191.

Referring to FIG. 2 and FIG. 4 again, in the implementation, the charging device 1 can further include a motor assembly 50. The motor assembly 50 is partially received in the first receiving space 100, connected to the second housing 20, and configured to drive the second housing 20 to rotate relative to the first housing 10.

In the implementation, to enable the second housing 20 to rotate relative to the first housing 10, the motor assembly 50 is provided. The motor assembly 50 is received in the first receiving space 100 in the first housing 10 and connected to the second housing 20, and when the motor assembly 50 is started, the motor assembly 50 can drive the second housing 20 to rotate relative to the first housing 10. As for a specific structure of the motor assembly 50, any structure that can drive the second housing 20 to rotate relative to the first housing 10 should fall within the protection scope of the disclosure, which will not be repeated in the disclosure.

The above explain the main components of the charging device 1 provided for solving the technical problems of the disclosure. The following will introduce in detail movement of the charging device 1 in the disclosure.

A process that the charging device 1 switches from the horizontal state to the vertical state is a switching process from the state in FIG. 2 to the state in FIG. 4, which can also be understood as a process that the holder 40 switches from the receiving state to the extending-out state. Specifically, the holder 40 is received in the first housing 10 before the motor assembly 50 starts operation. When the motor assembly 50 is started, the motor assembly 50 drives the second housing 20 to rotate counterclockwise relative to the first housing 10, and rotation of the second housing 20 can drive, through the rotation frame 192, the third rotation shaft 191 to rotate counterclockwise in the third rotation recess 190 of the transmission member 70, and then the transmission member 70 is driven to rotate clockwise in a direction opposite a rotation direction of the third rotation shaft 191. Rotation of the transmission member 70 further drives the holder 40 to rotate clockwise, finally the holder 40 is rotated to a position where the holder 40 extends out of the first housing 10, and at this point, the holder 40 and the second housing 20 after rotation cooperate to define the positioning recess 41 to position the electronic device 2.

A process that the charging device 1 switches from the vertical state to the horizontal state is a switching process from the state in FIG. 4 to the state in FIG. 2, which can also be understood as a process that the holder 40 switches from the extending-out state to the receiving state. Specifically, the holder 40 partially extends out of the first housing 10 before the motor assembly 50 is started. When the motor assembly 50 is started, the motor assembly 50 drives the second housing 20 to rotate clockwise relative to the first housing 10. Rotation of the second housing 20 can drive, through the rotation frame 192, the third rotation shaft 191 to rotate clockwise in the third rotation recess 190 of the transmission member 70, and then the transmission member 70 is driven to rotate counterclockwise in the direction opposite the rotation direction of the third rotation shaft 191. Rotation of the transmission member 70 further drives the holder 40 to rotate counterclockwise, and finally the holder 40 is rotated to be received in the first housing 10.

In addition, in the disclosure, the charging device 1 can further include a processor 60 received in the first receiving space 100. The processor 60 is electrically connected to the motor assembly 50, configured to send a first control signal to the motor assembly 50 to start the motor assembly 50, and further configured to send a second control signal to the motor assembly 50 to stop the motor assembly 50. The processor 60 can send different control signals to control specific operations of the motor assembly 50. The following will describe specifically several implementations in which movement of the motor assembly 50 is controlled through cooperation between the processor 60 and other electronic structural members.

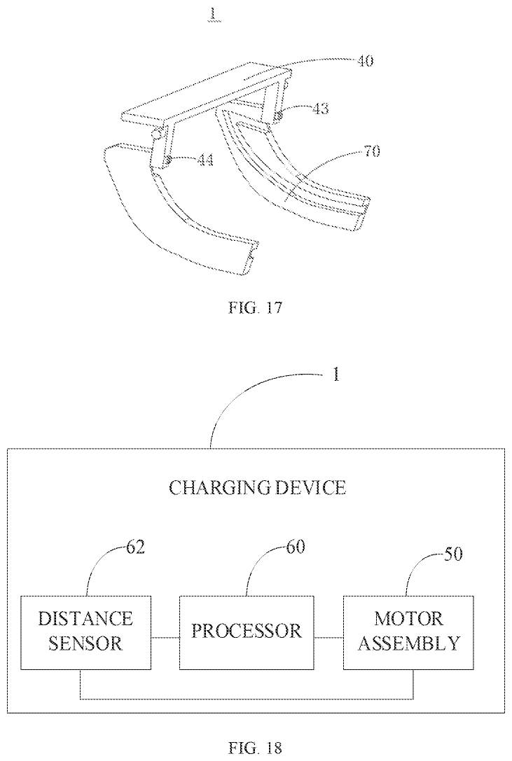

Referring to FIG. 18 together, FIG. 18 is a schematic structural view of an electronic structure of the charging device in an implementation of the disclosure. In the implementation, the charging device 1 can further include a distance sensor 62 received in the first receiving space 100. The distance sensor 62 is electrically connected to the processor 60 and connected to the motor assembly 50.

The processor 60 is configured to send the first control signal to the motor assembly 50 to start the motor assembly 50. During operation of the motor assembly 50, the distance sensor 62 is configured to send a distance signal to the processor 60, and the processor 60 is further configured to obtain a rotation angle of the second housing 20 according to the distance signal. The processor 60 is further configured to determine whether the rotation angle of the second housing 20 is greater than or equal to a preset angle, and further configured to send the second control signal to the motor assembly 50 to stop the motor assembly 50 in response to the rotation angle of the second housing 20 being greater than or equal to the preset angle.

In addition to the mechanical structural members of the charging device 1 described above, in the implementation, the charging device 1 may further include structural members with an electronic control function such as the processor 60 and the distance sensor 62. The distance sensor 62 is received in the first receiving space 100, connected to the motor assembly 50, and electrically connected to the processor 60. The processor 60 is configured to send the first control signal to the motor assembly 50 to start the motor assembly 50. During operation of the motor assembly 50, the distance sensor 62 is configured to detect a motion state (i.e., a distance that a slider slides) of at least a portion of the motor assembly 50 to obtain a distance signal, then the distance sensor 62 sends the distance signal to the processor 60, and the processor 60 can obtain the rotation angle of the second housing 20 relative to the first housing 10 according to the distance signal.

In addition, the processor 60 can also determine a relationship between the rotation angle of the second housing 20 and the preset angle. The preset angle may be pre-stored in the charging device 1 or obtained by the charging device 1 from the outside in real time, for example, the preset angle may be input to the charging device 1 by a user. The preset angle can be understood as a maximum rotation angle of the second housing 20 allowed by the charging device 1 or a rotation angle of the second housing 20 expected by the user.

When the rotation angle of the second housing 20 is greater than or equal to the preset angle, it means that the second housing 20 is rotated to an angle set by the user and is not expected to further rotate. Therefore, the processor 60 is further configured to send the second control signal to the motor assembly 50 to stop the motor assembly 50, thereby stopping rotation of the second housing 20, and the charging device 1 is finally in the vertical state required by the user.

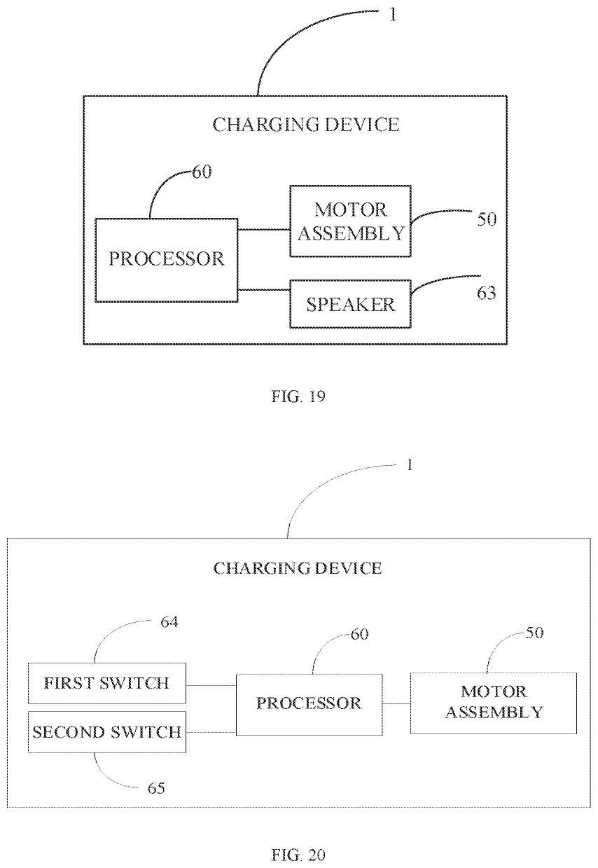

Referring to FIG. 19 together, FIG. 19 is a schematic structural view of an electronic structure of the charging device in another implementation of the disclosure. In the implementation, the charging device 1 can further include a speaker 63 received in the first receiving space 100 and electrically connected to the processor 60. The processor 60 is further configured to send an audio signal to the speaker 63 to make the speaker 63 sound when the processor 60 sends the first control signal to the motor assembly 50. The processor 60 is further configured to stop sending the audio signal to the speaker 63 when the processor 60 sends the second control signal to the motor assembly 50.

In the implementation, the speaker 63 is provided in the first receiving space 100 and is electrically connected to the processor 60. When the processor 60 sends the first control signal to the motor assembly 50, the motor assembly 50 starts operation, and at this point, the processor 60 can send the audio signal to the speaker 63 to make the speaker 63 sound. The motor assembly 50 may produce slight noise during operation. Sound of the speaker 63 can be used to make the noise be not heard, which improves user experience in combination with movement of the charging device 1. In addition, when the processor 60 sends the second control signal to the motor assembly 50 to stop the motor assembly 50, the motor assembly 50 does not sound, and at this point, the processor 60 can stop sending the audio signal to the speaker 63 to make the speaker 63 not sound. Moreover, a time point at which the charging device 1 starts operation and a time point at which the charging device 1 stops operation can also be known by a user according to a time point at which the speaker 63 sounds. Optionally, the first housing 10 defines multiple speaker holes to facilitate transmission of the sound emitted by the speaker 63 to the outside of the charging device 1.

Referring to FIG. 20 together, FIG. 20 is a schematic structural view of an electronic structure of the charging device in yet another implementation of the disclosure. In the implementation, the charging device 1 can further include a first switch 64 and a second switch 65 received in the first receiving space 100, and both the first switch 64 and the second switch 65 are electrically connected to the processor 60. The first switch 64 is configured to send a vertical signal to the processor 60 in response to pressing of the first switch 64, the processor 60 is further configured to send the first control signal to the motor assembly 50 according to the vertical signal, and the motor assembly 50 is configured to drive the second housing 20 to rotate in a first direction according to the first control signal. The second switch 65 is configured to send a horizontal signal to the processor 60 in response to pressing of the second switch 65, the processor 60 is further configured to send a third control signal to the motor assembly 50 according to the horizontal signal, and the motor assembly 50 is configured to drive the second housing 20 to rotate in a second direction according to the third control signal, where the first direction is opposite to the second direction.

In the implementation, the first switch 64 and the second switch 65 are provided in the first receiving space 100, connected to the first housing 10, and are electrically connected to the processor 60. The first switch 64 and the second switch 65 are structural members that are configured to control a time when the charging device 1 starts operation. Both the first switch 64 and the second switch 65 can be pressed. The first switch 64 can send the vertical signal to the processor 60 in response to pressing of the first switch 64, and the processor 60 can send the first control signal to the motor assembly 50 according to the vertical signal, thereby starting the motor assembly 50, and the motor assembly 50 can drive the second housing 20 to rotate in the first direction according to the first control signal. It can also be understood as that when the first switch 64 is pressed, the motor assembly 50 starts operation to switch the charging device 1 from the horizontal state to the vertical state. The second switch 65 can send the horizontal signal to the processor 60 in response to pressing of the second switch 65, the processor 60 is further configured to send the third control signal to the motor assembly 50 according to the horizontal signal, thereby restarting the motor assembly 50, and the motor assembly 50 is configured to drive the second housing 20 to rotate in the second direction according to the third control signal. It can also be understood as that when the second switch 65 is pressed, the motor assembly 50 starts operation to switch the charging device 1 from the vertical state to the horizontal state.

To sum up, the first switch 64 controls the charging device 1 to switch from the horizontal state to the vertical state. The second switch 65 controls the charging device 1 to switch from the vertical state to the horizontal state. The state of the charging device 1 can be controlled by pressing of the two switches, which improves operation convenience.

Referring to FIG. 20 again, in the implementation, the processor 60 is further configured to obtain a pressing duration of the first switch 64 according to the vertical signal and determine whether the pressing duration is less than a preset duration. The processor 60 is configured to send the second control signal to the motor assembly 50 in response to the pressing duration being less than the preset duration and the rotation angle of the second housing 20 being equal to the preset angle. Alternatively, the processor 60 is configured to send the second control signal to the motor assembly 50 in response to the pressing duration being greater than or equal to the preset duration and removal of a touch force on the first switch 64.

In the case where the first switch 64 is pressed, that is, during switching of the charging device 1 from the horizontal state to the vertical state, the second housing 20 cannot always rotate relative to the first housing 10, and thus the motor assembly 50 needs to be stopped after the second housing 20 rotates to a certain angle, thereby stopping rotation of the second housing 20. In the implementation, the processor 60 further can obtain the pressing duration of the first switch 64 according to the vertical signal, and determine a relationship between the pressing duration and the preset duration. The preset duration may be pre-stored in the charging device 1 or obtained by the charging device 1 from the outside in real time.

In the implementation, two control modes are provided according to the relationship between the pressing duration and the preset duration. In one control mode, the processor 60 sends the second control signal to the motor assembly 50 to stop the motor assembly 50 in response to the pressing duration being less than the preset duration and the rotation angle of the second housing 20 being equal to the preset angle. It can also be understood as that when the second housing 20 rotates to a maximum angle, the processor 60 can control the motor assembly 50 to stop operation. In the other control mode, the processor 60 can send the second control signal to the motor assembly 50 to stop the motor assembly 50 in response to the pressing duration being greater than or equal to the preset duration and removal of the touch force on the first switch 64. It can also be understood as that in the case where the pressing duration of the first switch 64 is greater than the preset duration, at any time a pressing force of the user is removed, the motor assembly 50 can be controlled to stop operation, and the second housing 20 can stop rotation at any position.

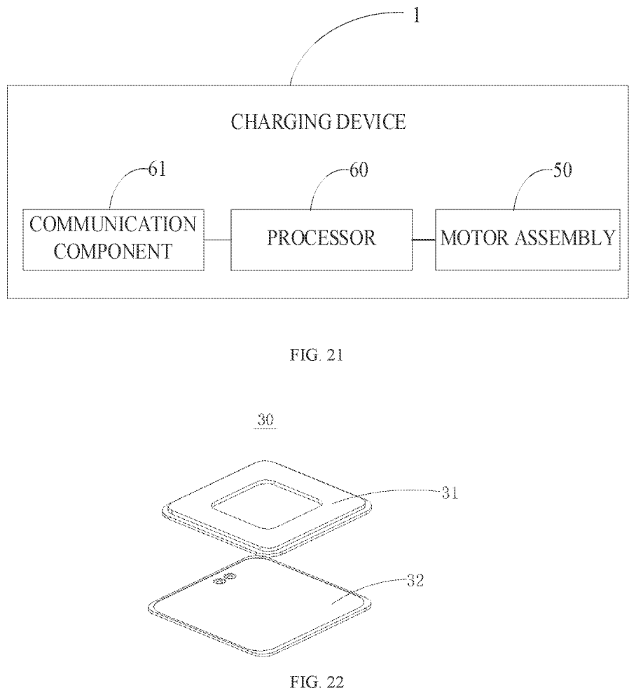

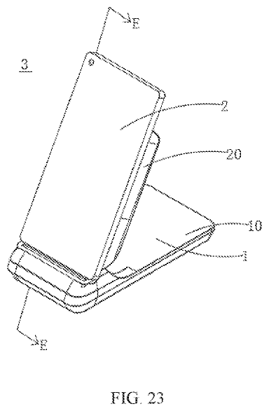

Referring to FIG. 21 together, FIG. 21 is a schematic structural view of an electronic structure of a charging device in yet another implementation of the disclosure. In the implementation, the charging device 1 can further include a communication component 61 received in the first receiving space 100. The communication component 61 is electrically connected to the processor 60 and configured to receive a fourth control signal from a terminal device. The communication component 61 is further configured to send the fourth control signal to the processor 60, and the processor 60 is further configured to start or stop the motor assembly 50 according to the fourth control signal.

In the implementation, the communication component 61 is provided in the first receiving space 100 and is electrically connected to the processor 60. The communication component 61 is configured to receive the fourth control signal from the terminal device. The terminal device may be an external device such as a mobile phone, a computer, a server, etc. These devices may send the fourth control signal. The communication component 61 then receives and sends the fourth control signal to the processor 60, and the processor 60 can control operation of the motor assembly 50 according to the fourth control signal, such that the second housing 20 can rotate relative to the first housing 10, and thus realizing switching of the charging device 1 between the horizontal state and the vertical state. Optionally, the communication component 61 can include, but is not limited to, wireless fidelity (wifi), a Bluetooth, near field communication (NFC), or the like.

Referring to FIG. 2, FIG. 4, and FIG. 22 together, FIG. 22 is an exploded view of the charging assembly in an implementation of the disclosure. In the implementation, the second housing 20 can include the third sub-housing 21 and the fourth sub-housing 22 connected to the third sub-housing 21. The third sub-housing 21 is closer to the first sub-housing 11 than the fourth sub-housing 22. The third sub-housing 21 and the fourth sub-housing 22 cooperate to define the third receiving space 200. The charging assembly 30 is received in the third receiving space 200. The charging assembly 30 can include the charging coil 31 and a heat dissipation support 32. The charging coil 31 is disposed on the heat dissipation support 32 and electrically connected to the processor 60. The processor 60 is further configured to send a charging signal to the charging coil 31 and the charging coil 31 is configured to charge the electronic device 2 according to the charging signal.

In the implementation, the third receiving space 200 is defined in the second housing 20, and the charging assembly 30 is received in the third receiving space 200. The charging assembly 30 may include the charging coil 31 and the heat dissipation support 32. The charging coil 31 is a structural member mainly configured to charge the electronic device 2. The heat dissipation support 32 is configured to carry the charging coil 31 and dissipates heat from the charging coil 31, so as to discharge in time the heat generated by operation of the charging coil 31 and improve a heat dissipation performance of the charging coil 31. In addition, the charging coil 31 is electrically connected to the processor 60, the processor 60 is further configured to send the charging signal to the charging coil 31 and the charging coil 31 is configured to charge the electronic device 2 according to the charging signal. Optionally, the charging coil 31 may be the wired charging coil 31 or the wireless charging coil 31. For example, in the implementation, the charging coil 31 is the wireless charging coil 31, and in this case, the charging device 1 is the wireless charging device 1, which can further improve convenience of usage of the charging device 1.

In addition, the charging assembly 30 may further include a refrigeration member.

The refrigeration member is disposed on the heat dissipation support 32 and configured to cool the charging coil 31. Specifically, the refrigeration member is electrically connected to the processor 60, the processor 60 is further configured to send a cooling signal to the refrigeration member, and the refrigeration member is configured to cool the charging coil 31 according to the cooling signal, thereby further discharging in time the heat generated by operation of the charging coil 31 and further improving the heat dissipation performance of the charging coil 31. Optionally, the refrigeration member can include, but is not limited to, a thermo-electronic chip (TEC).

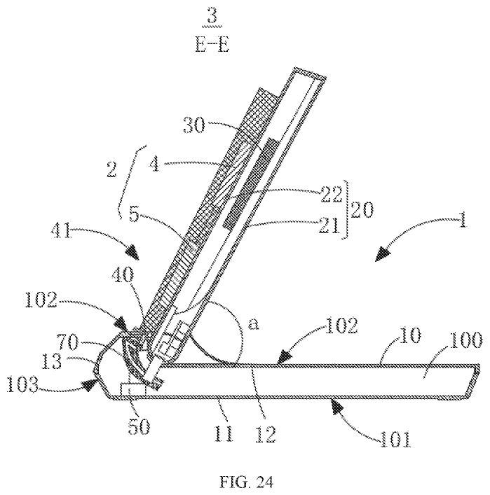

Referring to FIGS. 23-24, FIG. 23 is a schematic structural view of an electronic device assembly in an implementation of the disclosure, and FIG. 24 is a schematic cross-sectional view of the electronic device assembly in FIG. 23, taken along line E-E. An electronic device assembly 3 is provided in an implementation. The electronic device assembly 3 can include an electronic device 2 and the charging device 1 provided in the above implementations of the disclosure. The electronic device 2 can include an induction coil 4 and a battery 5, and the charging coil 31 and the induction coil 4 cooperate to charge the battery 5.

In addition to the specific structure of the charging device 1, the electronic device assembly 3 with the charging device 1 is also provided in the disclosure. In the implementation, the electronic device assembly 3 can include the electronic device 2 and the charging device 1 provided in the above implementations of the disclosure. The electronic device 2 can include, but is not limited to, a mobile terminal device such as a mobile phone, a tablet computer, a notebook computer, a palmtop computer, a PC, a PDA, a PMP, a navigation apparatus, a wearable device, a smart bracelet, or a pedometer, or a fixed terminal device such as a digital TV, a desktop computer, etc. The electronic device 2 can include the induction coil 4 and the battery 5. When the charging device 1 starts charging, the charging coil 31 and the induction coil 4 cooperate to charge the battery 5. In the electronic device assembly 3 provided in the implementation, by adopting the charging device 1 provided in the above implementations of the disclosure, the holder 40 can not only extend out of the first housing 10 to limit the electronic device 2 when the charging device 1 is in the vertical state, but also be received in the first housing 10 when the charging device 1 is in the horizontal state, thereby improving surface flatness of the charging device 1 and diversity and convenience of the electronic device assembly 3.

The contents provided in the above implementations of the disclosure are introduced in detail. Principles and implementations of the disclosure are elaborated and explained herein. The above illustrations are only used to help understanding of methods and core ideas of the disclosure. Moreover, for those of ordinary skill in the art, according to ideas of the disclosure, there will be changes in the specific implementations and application scopes. In summary, contents of this specification should not be understood as limitation on the disclosure.

What is claimed is:

1. A charging device, comprising:
a first housing;
a second housing rotatably connected to the first housing and configured to hold an electronic device;
a charging assembly received in the second housing and configured to charge the electronic device; and
a holder rotatable relative to the first housing and rotatable along with rotation of the second housing, and the holder being configured to switch between an extending-out state where a portion of the holder extends out of the first housing and a receiving state where the portion of the holder is received in the first housing.

2. The charging device of claim 1, further comprising a transmission member connected to the holder and the second housing, wherein when the second housing rotates relative to the first housing, the second housing drives the holder to rotate through indirection cooperation between the transmission member and the holder.

3. The charging device of claim 2, wherein:
the first housing comprises a first sub-housing and a second sub-housing connected to the first sub-housing, wherein the first sub-housing and the second sub-housing cooperate to define a first receiving space;
the first housing further comprises a protruding portion provided at a side of the second sub-housing away from the first sub-housing, wherein the protruding portion has two opposite first side walls and a second side wall connected between the two first side walls, wherein the first side walls and the second side wall cooperate to define a second receiving space connected to the first receiving space; and
the second housing is rotatably connected to the first side walls.

4. The charging device of claim 3, wherein:
the first side wall defines a first rotation recess at a side close to the second receiving space;
the second housing comprises a third sub-housing and a fourth sub-housing connected to the third sub-housing, wherein the third sub-housing is closer to the first sub-housing than the fourth sub-housing, the third sub-housing and the fourth sub-housing cooperate to define a third receiving space, and the third sub-housing has a bottom wall and a sidewall that is connected to and bent relative to at least a portion of a periphery of the bottom wall, wherein the sidewall defines a first through hole; and
the charging device further comprises a first rotation shaft, wherein the first rotation shaft has one end received in the third receiving space and connected to the third sub-housing, and another end of the first rotation shaft penetrates the first through hole, and the other one end of the first rotation shaft is disposed outside of the third receiving space and received in the first rotation recess.

5. The charging device of claim 3, wherein:
the first side wall defines a second rotation recess at a side close to the second receiving space;
the charging device further comprises a second rotation shaft, wherein the second rotation shaft has one end connected to the holder, and another end of the second rotation shaft is received in the second rotation recess; and
the holder defines a slot at a side close to the first sub-housing, and the end of the second rotation shaft is received in the slot.

6. The charging device of claim 3, wherein:
the protruding portion further has a top wall connected to the two first side walls and the second side wall, wherein the first side walls, the second side wall, and the top wall cooperate to define the second receiving space, the top wall defines a second through hole that is connected to the second receiving space, and the top wall defines a second rotation recess at a wall of the second through hole; and
the charging device further comprises a second rotation shaft, wherein the holder is partially received in the second through hole, and the second rotation shaft has an end connected to the holder, and another end of the second rotation shaft is received in the second rotation recess.

7. The charging device of claim 6, wherein when the holder is in the receiving state, a side surface of the holder away from the first sub-housing is flush with a side surface of the top wall away from the first sub-housing.

8. The charging device of claim 3, further comprising an anti-slip member that is disposed at a side of the holder away from the first sub-housing.

9. The charging device of claim 3, wherein:
the transmission member is partially received in the second receiving space, and the transmission member is connected to the holder and defines a third rotation recess; and
the charging device further comprises a rotation frame and a third rotation shaft, wherein the rotation frame is connected to the second housing at a side of the second housing close to the holder, and the third rotation shaft has an end connected to the rotation frame, and another opposite end of the third rotation shaft is received in the third rotation recess.

10. The charging device of claim 9, wherein the third rotation recess is in a shape of arc and extends towards the first sub-housing, and the third rotation recess extends in a direction parallel to a rotation direction of the third rotation shaft.

11. The charging device of claim 9, wherein:
the transmission member defines an installation groove at a side close to the second housing, wherein the installation groove is connected to the third rotation recess;
the transmission member defines the third rotation recess at a side away from the first side wall, and the third rotation shaft has an end connected to the rotation frame at a side of the rotation frame close to the first side wall; and
the holder defines a fixing hole at one end close to the first sub-housing, and the transmission member is provided with a connecting rod shaft received in the fixing hole.

12. The charging device of claim 3, further comprising a motor assembly, wherein the motor assembly is received in the first receiving space, connected to the second housing, and configured to drive the second housing to rotate relative to the first housing.

13. The charging device of claim 12, further comprising a processor received in the first receiving space, wherein the processor is electrically connected to the motor assembly, configured to send a first control signal to the motor assembly to start the motor assembly, and further configured to send a second control signal to the motor assembly to stop the motor assembly.

14. The charging device of claim 13, further comprising a distance sensor received in the first receiving space, wherein the distance sensor is electrically connected to the processor and connected to the motor assembly, and wherein
during operation of the motor assembly, the distance sensor is configured to send a distance signal to the processor, and the processor is further configured to obtain a rotation angle of the second housing according to the distance signal, and wherein the processor is further configured to determine whether the rotation angle of the second housing is greater than or equal to a preset angle, and further configured to send the second control signal to the motor assembly to stop the motor assembly in response to the rotation angle of the second housing being greater than or equal to the preset angle.

15. The charging device of claim 13, further comprising a speaker received in the first receiving space and electrically connected to the processor, wherein
the processor is further configured to:
send an audio signal to the speaker to make the speaker sound when the processor sends the first control signal to the motor assembly; or
stop sending the audio signal to the speaker when the processor sends the second control signal to the motor assembly.

16. The charging device of claim 13, further comprising a first switch and a second switch received in the first receiving space, wherein both the first switch and the second switch are electrically connected to the processor, and wherein the first switch is configured to send a vertical signal to the processor in response to pressing of the first switch, and the processor is further configured to send the first control signal to the motor assembly according to the vertical signal, and the motor assembly is configured to drive the second housing to rotate in a first direction according to the first control signal; and
the second switch is configured to send a horizontal signal to the processor in response to pressing of the second switch, and the processor is further configured to send a third control signal to the motor assembly according to the horizontal signal, and the motor assembly is configured to drive the second housing to rotate in a second direction according to the third control signal, wherein the first direction is opposite to the second direction.

17. The charging device of claim 16, wherein:
the processor is further configured to obtain a pressing duration of the first switch according to the vertical signal and determine whether the pressing duration is less than a preset duration; and
the processor is further configured to perform one of the following:
send the second control signal to the motor assembly in response to the pressing duration being less than the preset duration and a rotation angle of the second housing being equal to the preset angle; and
send the second control signal to the motor assembly in response to the pressing duration being greater than or equal to the preset duration and removal of a touch force on the first switch.

18. The charging device of claim 13, further comprising a communication component received in the first receiving space, wherein:
the communication component is electrically connected to the processor and configured to receive a fourth control signal from a terminal device; and
the communication component is further configured to send the fourth control signal to the processor, and the processor is further configured to start or stop the motor assembly according to the fourth control signal.

19. The charging device of claim 13, wherein:
the second housing comprises a third sub-housing and a fourth sub-housing connected to the third sub-housing, wherein the third sub-housing is closer to the first sub-housing than the fourth sub-housing, and the third sub-housing and the fourth sub-housing cooperate to define a third receiving space; and
the charging assembly is received in the third receiving space and comprises a charging coil and a heat dissipation support, wherein the charging coil is disposed on the heat dissipation support and electrically connected to the processor, and the processor is further configured to send a charging signal to the charging coil, and the charging coil is configured to charge the electronic device according to the charging signal.

20. The charging device of claim 1, wherein:
the first housing has a first surface, a second surface opposite the first surface, and a third surface connecting the first surface and the second surface, wherein the second surface is configured to partially abut against the second housing, and when the holder is in the extending-out state, the holder extends out of the first housing from the second surface; and
the charging device has a horizontal state and a vertical state, wherein in the horizontal state, the second housing is parallel to the first housing, in the vertical state, the second housing is angled relative to the first housing, and when the charging device is in the vertical state, the holder is perpendicular to the second housing.
